(19) United States
(12) Patent Application Publication
(10) Pub. No.: US 2017/0033759 A1
(43) Pub. Date: Feb. 2, 2017

(54) BAND-PASS FILTER AND WIRELESS COMMUNICATION APPARATUS

(71) Applicant: KABUSHIKI KAISHA TOSHIBA, Tokyo (JP)

(72) Inventors: Shigehito SAIGUSA, Yokohama Kanagawa (JP); Mai ARAKI, Kawasaki Kanagawa (JP); Tadashi ARAI, Yokohama Kanagawa (JP); Makoto MORITA, Zushi Kanagawa (JP); Shoji OOTAKA, Yokohama Kanagawa (JP)

(21) Appl. No.: 15/220,075

(22) Filed: Jul. 26, 2016

(30) Foreign Application Priority Data
Jul. 27, 2015 (JP) 2015-148044

(51) Int. Cl. H03H 7/01; H04B 1/10; H03H 7/06

(52) U.S. Cl. CPC H03H 7/0161; H03H 7/06; H04B 1/10

(57) ABSTRACT

A band-pass filter circuit includes a low-pass filter, a high-pass filter including an integrator, and a controller. The controller is configured to increase a cut-off frequency of the high-pass filter for a predetermined period of time, when changing a gain of the low-pass filter. Further, the controller is configured to increase a cut-off frequency of the low-pass filter or decrease a Q value of the low-pass filter for the predetermined period of time.

### CROSS-REFERENCE TO RELATED APPLICATION

This application is based upon and claims the benefit of priority from Japanese Patent Application No. 2015-148044, filed Jul. 27, 2015, the entire contents of which are incorporated herein by reference.

### FIELD

Embodiments described herein relate generally to a band-pass filter and a wireless communication apparatus.

### BACKGROUND

In the related art, a receiver for wireless communication includes a low-pass filter that extracts only a desired signal from signals received from an antenna, and a variable gain amplifier that is capable of changing a gain in order to optimize the intensity of a signal output to an analog-to-digital converter which performs conversion into a digital signal.

Further, a variable gain amplifier of one type may include a DC offset removal circuit that reduces a DC (Direct Current) offset.

A method for causing a transient DC offset to rapidly converge would be switching a cut-off frequency of a high-pass filter. However, when a filter having a function of the variable amplifier is connected in series to a low-pass filter, ringing may occur in an output of the low-pass filter even if the cut-off frequency of the high-pass filter is switched. As a result, the transient DC offset may not rapidly settle.

### DESCRIPTION OF THE DRAWINGS

FIG. 1 is a block diagram illustrating a configuration of a receiver of a wireless communication apparatus according to a first embodiment.

FIG. 2 is a block diagram illustrating a configuration of a low pass filter-variable gain amplifier (LPF-VGA) in the receiver according to the first embodiment.

FIG. 3 is a circuit diagram illustrating a biquad filter and a DC offset removal circuit in the LPF-VGA.

FIG. 4 is a circuit diagram illustrating an integrator in the LPF-VGA.

FIG. 5 is a flowchart illustrating a process for rapid convergence of a DC offset carried out in the receiver according to the first embodiment.

FIG. 6 schematically illustrates frequency characteristics of the LPF-VGA serving as a band-pass filter when a resistance of a register and capacities of capacitors are changed.

FIG. 7 illustrates a transient response characteristic of the DC offset when the process for rapid convergence of the DC offset is performed according to the first embodiment.

FIG. 8 illustrates the transient response characteristic of the DC offset when only the cut-off frequency of the HPF is switched without performing the process for the rapid convergence of the DC offset according to the first embodiment.

FIG. 9 is a circuit diagram of a biquad filter and a DC offset removal circuit according to a second embodiment.

FIG. 10 is a flowchart illustrating a process for rapid convergence of DC offset according to the second embodiment.

FIG. 11 illustrates the transient response characteristic of the DC offset when the process for the rapid convergence of the DC offset according to the second embodiment is performed.

FIG. 12 is a circuit diagram of a biquad filter and a DC offset removal circuit according to a third embodiment.

FIG. 13 is a flowchart illustrating a process for rapid convergence of DC offset according to the third embodiment.

### DETAILED DESCRIPTION

Certain embodiments provide a band-pass filter that can change a gain and cause a transient DC offset which is generated when the gain is changed to rapidly converge, and a wireless communication apparatus including such a band-pass filter.

According to one embodiment, a band-pass filter circuit includes a low-pass filter, a high-pass filter comprising an integrator, and a controller. The controller is configured to increase a cut-off frequency of the high-pass filter for a predetermined period of time, when changing a gain of the low-pass filter. Further, the controller is configured to increase a cut-off frequency of the low-pass filter or decrease a Q value of the low-pass filter for the predetermined period of time.

Hereinafter, embodiments are described with reference to the accompanying drawings.

### First Embodiment

### Configuration

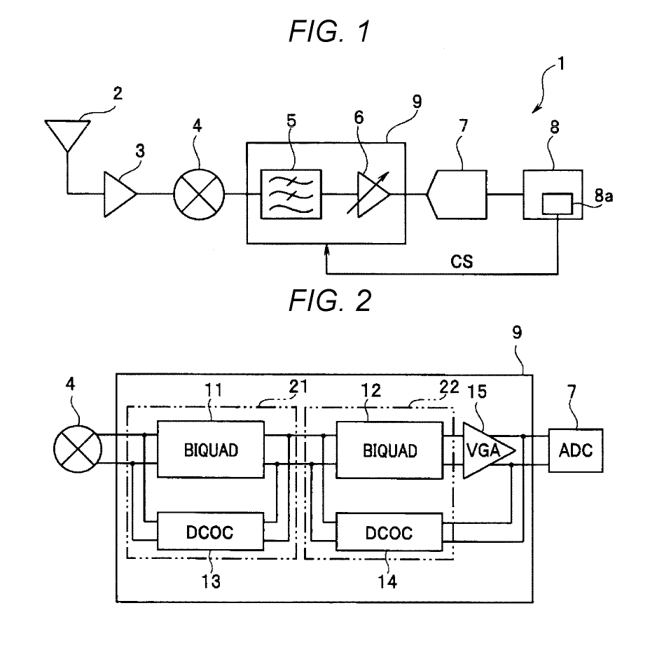

FIG. 1 is a block diagram illustrating the basic configuration of a receiver of a wireless communication apparatus according to this embodiment.

A wireless receiver 1 for wireless communication includes an antenna 2, a low-noise amplifier (hereinafter, abbreviated to LNA) 3, a mixer 4 that performs frequency conversion, a low-pass filter (hereinafter, abbreviated to LPF) 5, a variable gain amplifier (hereinafter, abbreviated to VGA) 6, an analog-to-digital converter (hereinafter, abbreviated to ADC) 7, and a digital base band section (hereinafter, abbreviated to DBB) 8.

A signal that is received by the antenna 2 is amplified by the LNA 3, and is down-converted into a base-band signal by the mixer 4. The base-band signal, which is acquired through down-converter, is amplified to a desired amplification level by the VGA 6 after interfering wave signals other than signals which are desired to be received are removed by the LPF 5 such that appropriate conversion is performed in the ADC 7. The base-band signal, which is converted into a digital signal in the ADC 7, is demodulated by the DBB 8.

The LPF 5 and the VGA 6 are not separate circuits, and are configured to be a low-pass filter (hereinafter, abbreviated to LPF-VGA) 9 provided with a variable gain amplifying function in which the function of the VGA 6 is provided to the LPF 5 in order to reduce the number of amplifiers which are components and to lower current consumption. A DC offset removal circuit is inserted into the VGA 6.

The DBB 8 includes a controller 8a which controls the LPF-VGA 9. The controller 8a outputs various control signals CS to the LPF-VGA 9. A circuit which includes the LNA 3, the mixer 4 and the LPF-VGA 9 is integrated in a semiconductor device.

FIG. 2 is a block diagram illustrating an example of the basic configuration of the LPF-VGA 9. The LPF-VGA 9 includes two biquad filters (BIQUAD) 11 and 12, two DC offset removal circuits (DCOC) 13 and 14, and a VGA 15.

Each of the biquad filters 11 and 12 has a second-order LPF function and a VGA function. The LPF-VGA 9 of FIG. 2 is a fourth-order LPF in which the two biquad filters 11 and 12 are connected in a cascade manner.

In addition, when the VGA 15 is provided at the rear stage of the biquad filter 12 at a second stage, the LPF-VGA 9 can perform a more precise gain adjustment. Furthermore, in the LPF-VGA 9, the DC offset removal circuits 13 and 14 are respectively added to the biquad filters 11 and 12.

In the LPF-VGA 9, biquad filters are used. However, a filter other than a biquad filter may be used if the filter has the functions of the LPF and the VGA.

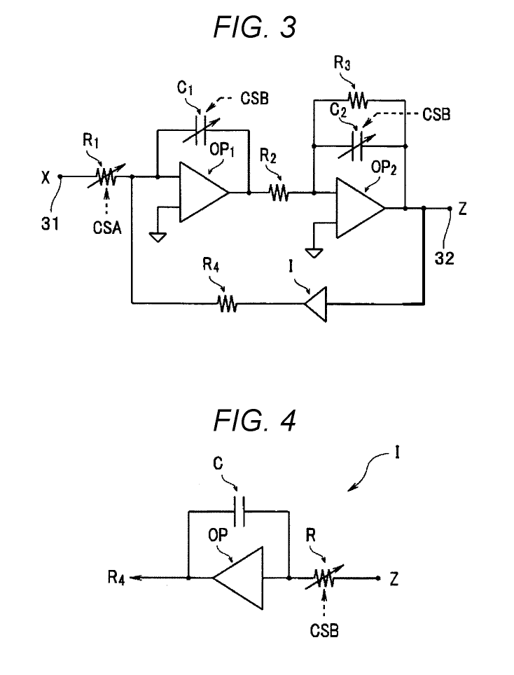

Subsequently, the configuration of a circuit module 21, which is depicted by a two-short dashed line in FIG. 2 and includes the biquad filter 11 and a DC offset removal circuit 13 is described. FIG. 3 is a circuit diagram depicting circuit 21 which includes the biquad filter 11 and the DC offset removal circuit 13. The biquad filter 12 and the DC offset removal circuit 14 excluding the VGA 15 also have the same configuration as in FIG. 3. That is, in FIG. 2, the configuration of a circuit module 22 which is depicted by a two-short dashed line and includes the biquad filter 12 and the DC offset removal circuit 14 is the same as in FIG. 3.

The circuit illustrated in FIG. 3 performs the three functions of low pass filter, variable gain amplifier and DC offset removal. In a first active filter stage, an input signal X from an input terminal 31 is input to the negative input of an operational amplifier OP₁ through a variable resistor R₁. A variable capacitor C₁ is connected between the output and the negative input of the operational amplifier OP₁. The operational amplifier OP₁, the variable resistor R₁, and the variable capacitor C₁ make up one integrator.

The output of the operational amplifier OP₁ is input to a second active filter stage via resistor R₂ to the negative input of an operational amplifier OP₂. A variable capacitor C₂ and a resistor R₃ are connected in parallel between the output and the negative input of the operational amplifier OP₂. The operational amplifier OP₂ generates an output signal Z to an output terminal 32. The operational amplifier OP₂, the resistor R₂, and the variable capacitor C₂ make up another integrator.

The first stage (the first active filter stage) is a complete integrator which includes the variable resistor R₁ as an input resistor, the operational amplifier OP₁, and the variable capacitor C₁ as a feedback capacitance. The second stage (the second active filter stage) is an incomplete integrator which includes the resistor R₂ as an input resistor, the operational amplifier OP₂, the variable capacitor C₂ as a feedback capacitance, and the resistor R₃ as a feedback resistor.

In addition, an integrator I is connected between the negative input of the operational amplifier OP₁ and the output of the operational amplifier OP₂, and the output of the integrator I is input to the negative input of the operational amplifier OP₁ through a resistor R₄.

FIG. 4 is a circuit diagram of the integrator I. The integrator I includes a variable resistor R, an operational amplifier OP, and a capacitor C. The integrator I changes a band thereof by changing a resistance R of the variable resistor R. The output of the operational amplifier OP₂ is input to the operational amplifier OP through the variable resistor R. A capacitor C is connected between the negative input and the output of the operational amplifier OP.

Meanwhile, the integrator I changes the band by changing resistance R of the variable resistor. However, it is possible to change the band by changing the capacitance C of the variable capacitor C.

DC offset removal is realized by inserting the integrator I, which is a first-order LPF, into the feedback path (feedback loop) of the second-order LPF, and has the characteristic of the high-pass filter (hereinafter, abbreviated to HPF) of the LPF-VGA 9.

When it is assumed that R₁, R₂, R₃ and R₄ denote the resistances of the resistors R₁, R₂, R₃ and R₄, respectively, C₁ and C₂ denote the capacitances of the capacitors C₁ and C₂, respectively, ω_{C} denotes a cut-off frequency, Q denotes the Q value, and A denotes the gain, a transfer function (Z/X) of the circuit illustrated in FIG. 3, assuming I=1, is expressed in the following Equation (1).

$$\begin{matrix}\frac{Z}{X} = \frac{1}{{s}^{2} {C}_{1} {C}_{2} {R}_{1} {R}_{2} + {sC}_{1} \frac{{R}_{1} {R}_{2}}{{R}_{3}} + \frac{{R}_{1}}{{R}_{4}}} \\ = \frac{\frac{{R}_{4}}{{R}_{1}}}{{s}^{2} {C}_{1} {C}_{2} {R}_{2} {R}_{4} + {sC}_{1} \frac{{R}_{2} {R}_{4}}{{R}_{3}} + 1} = \frac{A}{\frac{{s}^{2}}{{ω}_{c}^{2}} + \frac{s}{{ω}_{c} Q} + 1}\end{matrix} \qquad ( 1 )$$

The cut-off frequency ω_{C} of the LPF is expressed in subsequent Equation (2).

$${ω}_{C} = \frac{1}{\sqrt{{C}_{1} {C}_{2} {R}_{2} {R}_{4}}} \qquad ( 2 )$$

The Q value is expressed in subsequent Equation (3).

$$Q = {R}_{3} \sqrt{\frac{{C}_{2}}{{C}_{1} {R}_{2} {R}_{4}}} \qquad ( 3 )$$

The gain A is expressed in subsequent Equation (4).

$$A = \frac{{R}_{4}}{{R}_{1}} \qquad ( 4 )$$

It is possible to change the gain A by changing the resistance R₁ of the resistor R₁.

It is possible to change the cut-off frequency ω_{C} (first cutoff frequency) of the LPF by changing the capacitances C₁ and C₂ of the capacitors C₁ and C₂.

It is possible to change the Q value of the LPF by changing at least one of the resistances of resistors R₂, R₃, and R₄ and the capacitances of the capacitors C₁ and C₂.

Further, it is possible to change the cut-off frequency ω_{C1} (a second cutoff frequency) when I in FIG. 3 is implemented as shown in FIG. 4 by changing at least one of the resistance R of the resistor R of the integrator I and the capacitance C of the capacitor C of the integrator I.

As above, the circuit illustrated in FIG. 3 with I implemented as in FIG. 4 makes up a band-pass filter that includes at least one integrator each including an amplifier, a resistor and a capacitor, that can change the gain A and that has the functions of the LPF and the HPF.

More specifically, the circuit illustrated in FIG. 3 with I implemented as in FIG. 4 includes three integrators, that is, a first integrator that includes the operational amplifier OP₁, the variable resistor R₁ and the variable capacitor C₁, a second integrator that includes the operational amplifier OP₂, the resistor R₂, the capacitor C₂, and the resistor R₃ and the integrator I which is a third integrator that includes the operational amplifier OP, the variable resistor R, and the capacitor C. The first integrator is the complete integrator, and the second integrator is the incomplete integrator. The third integrator is provided on the feedback path between the output of the second integrator and the input of the first integrator.

### (Operation)

The controller 8a of the DBB 8, for example, performs control that detects the signal level of a preamble signal in communication, and changes the gain A according to the detected signal level. The controller 8a outputs, as one of control signals CS, a control signal CSA to change the resistance R₁ of the resistor R₁ thereby changing the gain A.

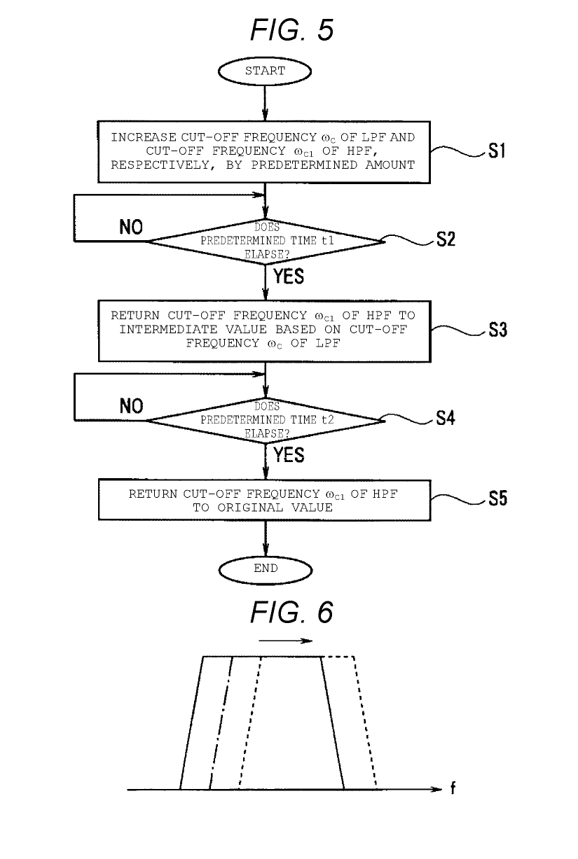

The controller 8a performs a process for rapid convergence of the DC offset when the gain A is changed. FIG. 5 is a flowchart illustrating an example of a flow of the process for the rapid convergence of the DC offset.

The process of FIG. 5 is performed simultaneously with the operation to change the gain A when the gain A is changed. The process of FIG. 5 is performed by a hardware circuit in the controller 8a. When the gain A is changed, the controller 8a outputs the control signal CS to the biquad filters 11 and 12, the DC offset removal circuits 13 and 14, and the VGA 15 in the LPF-VGA 9. The circuit illustrated in FIG. 3 and the controller 8a, which performs the process of FIG. 5, make up the band-pass filter.

When it is determined that the gain A is changed, the controller 8a increases the cut-off frequency ω_{C} of the LPF and the cut-off frequency ω_{C1} of the HPF in the circuit modules 21 and 22 by predetermined amounts PA1 and PA2, respectively (S1). For example, a control signal CSB that is sent to the LPF-VGA 9 changes the cut-off frequency ω_{C} of the LPF to a frequency which is twice the frequency before the change, that is, twice an original frequency and increases the cut-off frequency ω_{C1} of the HPF by several MHz.

The controller 8a outputs the control signal CSA to change the gain A to the variable resistors R₁ of the respective circuit modules 21 and 22 and the VGA 15.

The process in S1 is performed at the same timing as a timing at which the controller 8a outputs the control signal CSA to change the resistances R₁ of the variable resistors R₁ of the respective circuit modules 21 and 22 in order to change the gain A, and the control signal CSA and a control signal CSB are simultaneously output.

Accordingly, when the process in S1 is performed, the control signal CS, which is output to the LPF-VGA 9, includes the control signals CSA and CSB to change the resistance R₁ of the resistor R₁, the capacitances C₁ and C₂ of the capacitors C₁ and C₂, and the resistance R of the resistor R.

FIG. 6 is a graph schematically illustrating the frequency characteristics of the LPF-VGA 9 as a band-pass filter when the resistance R of the resistor R and the capacitances C₁ and C₂ of the capacitors C₁ and C₂ are changed.

In FIG. 6, the frequency characteristics of the LPF-VGA 9 before the gain A is changed are depicted by a solid line. When the gain A is changed, the frequency characteristics shift to a high band side through S1, to be one depicted by a dotted line in the graph. For example, it is possible to double the cut-off frequency ω_{C} of the LPF by halving the capacities C₁ and C₂ of the capacitors C₁ and C₂, respectively.

The transmissive frequency band of the LPF-VGA 9 as the band-pass filter shifts to a high frequency band through S1, as expressed by an arrow in FIG. 6.

The controller 8a determines whether or not a predetermined time t1 elapses after the process in S1 is performed (S2). If the predetermined time t1 has not elapsed (S2: NO), no further processing is performed. The predetermined time t1 is, for example, 0.3 μsec.

When the predetermined time t1 elapses (S2: YES), the controller 8a returns the cut-off frequency ω_{C1} of the HPF to an intermediate value based on the cut-off frequency ω_{C} of the LPF (S3). The cut-off frequency ω_{C} of the LPF is, for example, the frequency before the change is performed in S1. The intermediate value is, for example, the original frequency of the cut-off frequency ω_{C1} of the HPF and a half of the frequency which is changed during S1. The control signal CSB for S3 is output from the controller 8a to the LPF-VGA 9.

As above, the controller 8a controls two integrators for a predetermined period (t1) during which the gain is changed, so as to raise both of the cut-off frequency ω_{C} of the LPF and the cut-off frequency ω_{C1} of the HPF. Particularly, the controller 8a raises the cut-off frequency ω_{C} of the LPF by changing at least one, here, both of the capacitance of the capacitor C₁ of the complete integrator and the capacitance of the capacitor C₂ of the incomplete integrator. The controller 8a changes the cut-off frequency ω_{C1} of the HPF by changing the resistance R of the resistor R of the integrator I.

The cut-off frequency ω_{C1} of the HPF is changed as depicted by a dashed line in FIG. 6.

The controller 8a determines whether or not a predetermined time t2 has elapsed (S4) after performing the process in S3. If the predetermined time t2 has not elapsed (S4: NO), no further processing is performed. The predetermined time t2 is, for example, 0.7 μsec.

When the predetermined time t2 elapses (S4: YES), the controller 8a returns the cut-off frequency ω_{C1} of the HPF to the original cut-off frequency (S5). The original cut-off frequency ω_{C1} of the HPF is the frequency before the change is performed in S1. The control signal CS for S5 is output from the controller 8a to the LPF-VGA 9.

With the process in S5, the transmissive frequency band of the LPF-VGA 9 as the band-pass filter returns to the band before the gain A is changed, as depicted by the solid line in FIG. 6.

As above, if the predetermined period (t1) elapses, during a predetermined period (t2), the controller 8a returns the cut-off frequency ω_{C} of the LPF to the original frequency before the cut-off frequency ω_{C} is raised, and changes the cut-off frequency ω_{C1} of the HPF to a frequency having a value between the frequency before the frequency is raised and the raised frequency. If the predetermined period (t2) elapsed, the controller 8a controls the three integrators so that the cut-off frequency ω_{C1} returns to the original frequency before the cut-off frequency ω_{C1} of the HPF is raised.

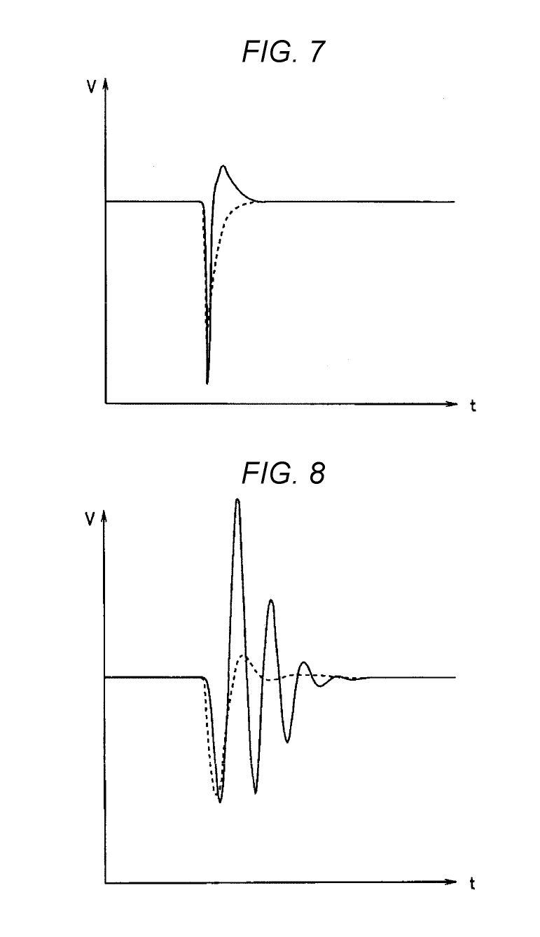

FIG. 7 is a graph illustrating the transient response characteristic of the DC offset when the process for the rapid convergence of the DC offset is performed according to this embodiment. The graph of FIG. 7 is acquired through simulation and shows qualitative characteristics. In FIG. 7, a horizontal axis indicates time t and a vertical axis indicates an offset voltage.

A solid line of FIG. 7 indicates a change in the offset output (voltage) of the VGA 15 of the LPF-VGA 9, and a dotted line indicates a change in the offset output (voltage) of the biquad filter 11 of the LPF-VGA 9.

FIG. 8 is a graph illustrating the transient response characteristic of the DC offset according to related art in which only the cut-off frequency of the HPF is switched without the process for the rapid convergence of the DC offset according to the embodiment being performed. The graph of FIG. 8 is acquired through simulation and shows qualitative characteristics.

A solid line of FIG. 8 indicates the change in the offset output (voltage) of the VGA 15 of the LPF-VGA 9, and a dotted line indicates the change in the offset output (voltage) of the biquad filter 11 of the LPF-VGA 9.

In the case of FIG. 8, the offset output (voltage) of the biquad filter 11 is not stable after being quickly changed, and the output of VGA 15, which is connected in a subsequent stage of the biquad filter 12, gradually converges while oscillating several times after the large change.

In contrast, as can be seen from FIG. 7, when the process for the rapid convergence of the DC offset is performed according to the embodiment, the offset output (voltage) of the biquad filter 11 is once quickly changed. However, the output of the VGA 15, which is connected in the subsequent stage of the biquad filter 12, rapidly converges.

Therefore, in the case of FIG. 8, when the convergence time of the offset output of the VGA 15 is long and exceeds a time which is predetermined based on communication standards, there is a concern that it is difficult to receive desired data. However, according to the embodiment, the offset output of the VGA 15 converges within the time which is predetermined based on the communication standards as illustrated in FIG. 7, and thus it is possible to receive desired data.

Therefore, according to this embodiment, in a filter which can change the gain, it is possible to supply a filter, which can cause the transient response signal of the DC offset generated when the gain is changed in a wireless communication apparatus.

### Second Embodiment

In the first embodiment, when the gain is changed, the cut-off frequency ω_{C} of the LPF of the LPF-VGA 9 and the cut-off frequency ω_{C1} of the HPF are raised only during the predetermined period, thereby accomplishing the rapid convergence of the DC offset. On the other hand, in this embodiment, when the gain is changed, the Q value of the LPF of the LPF-VGA 9 is lowered and the cut-off frequency ω_{C1} of the HPF is raised only during the predetermined period, thereby accomplishing the rapid convergence of the DC offset.

In the embodiment, the same reference numeral is attached to the same component as in the first embodiment and the description thereof is not repeated.

A wireless receiver according to this embodiment has the same configuration as in FIG. 1. The basic configuration of the LPF-VGA 9 has the same configuration as in FIG. 2.

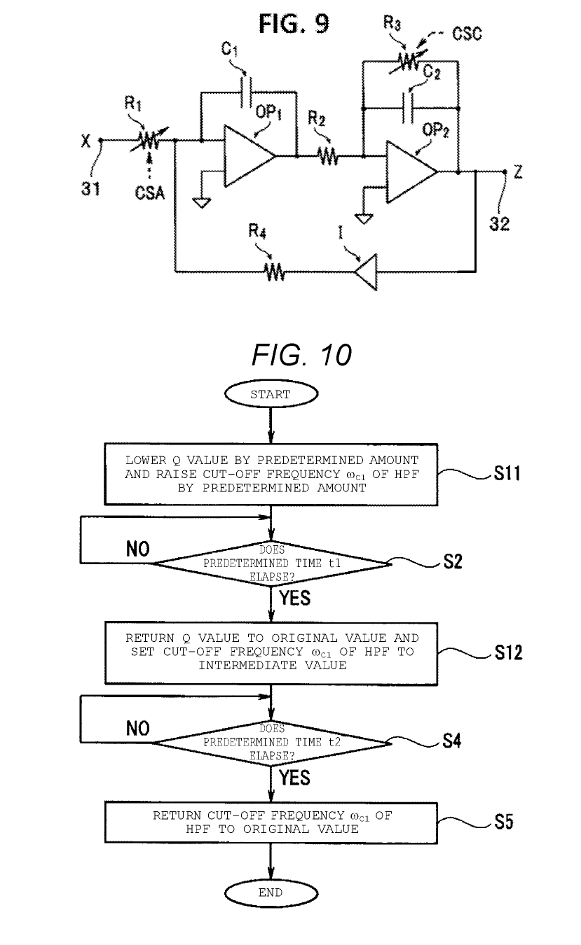

FIG. 9 is a circuit diagram including the biquad filter 11 and the DC offset removal circuit 13 according to this embodiment. In FIG. 2, the configuration of the circuit module 22, which includes the biquad filter 12 and the DC offset removal circuit 14 depicted by the two-short dashed line, is the same as the configuration in FIG. 9 except the VGA 15.

The circuit illustrated in FIG. 9 includes three functions of the LPF, the VGA and the DC offset removal, and has the approximately same configuration as in FIG. 3. However, the circuit is different from the circuit of FIG. 3 in that the capacitors C₁ and C₂ are not variable capacitors but fixed capacitors and that the resistor R₃ is a variable resistor instead.

The integrator I has the same configuration as in FIG. 4.

The controller 8a performs a process for rapid convergence of DC offset when the gain A is changed. FIG. 10 is a flowchart illustrating an example of a flow of the process for the rapid convergence of the DC offset. Meanwhile, in FIG. 10, the same step number is attached to a process which is the same as in FIG. 5, and description thereof is repeated.

The process in FIG. 10 is simultaneously performed with the operation to change the gain A when the gain A is changed. The process of FIG. 10 is performed by a hardware circuit of the controller 8a. When the gain A is changed, the controller 8a outputs a control signal CS to the biquad filters 11 and 12, the DC offset removal circuits 13 and 14, and the VGA 15 in the LPF-VGA 9.

If it is determined that the gain A is changed, the controller 8a lowers the Q value by a predetermined amount PQ and raises the cut-off frequency ω_{C1} of the HPF by a predetermined amount PA2 (S11). For example, it is possible to lower the Q value while maintaining the cut-off frequency φc of the LPF-VGA 9, by reducing the resistance of the variable resistor R₃. A control signal CSC to lower the Q value is output from the controller 8a to the LPF-VGA 9.

A process in S11 is performed at the same timing as a timing at which the controller 8a outputs the control signal CSA to change the resistances R₁ of the variable resistors R₁ of the circuit modules 21 and 22 in order to change the gain A. The control signal CSC is simultaneously output with the control signal CSA.

Therefore, when the process in S11 is performed, the control signal CS, which is output to the LPF-VGA 9, includes the control signal CSC to change the resistance R₃ of the resistor R₃.

While the process in S11 is performed, the controller 8a determines whether or not a predetermined time t1 elapses (S2). When the predetermined time t1 has not elapsed (S2: NO), nothing further is performed. The predetermined time t1 is, for example, 0.3 μsec.

When the predetermined time t1 elapses (S2: YES), the controller 8a returns the Q value to an original value, and returns the cut-off frequency ω_{C1} of the HPF to an intermediate value (S12). The intermediate value is, for example, an original frequency of the cut-off frequency ω_{C1} of the HPF and a half of the frequency which is changed through S11. The control signal CSC for S12 is output from the controller 8a to the LPF-VGA 9.

That is, the controller 8a controls the three integrators during the predetermined period (t1) according to the timing at which the gain is changed so that the Q value of the LPF is lowered and the cut-off frequency ω_{C1} of the HPF is raised. In particular, the controller 8a changes the Q value of the LPF by changing the resistance of the resistor R₃.

After the process in S12 is performed, the controller 8a determines whether or not a predetermined time t2 has elapsed (S4). When the predetermined time t2 has not elapsed (S4: NO), no further processing is performed. The predetermined time t2 is, for example, 0.7 μsec.

When the predetermined time t2 elapses (S4: YES), the controller 8a returns the cut-off frequency ω_{C1} of the HPF to an original cut-off frequency (S5). The original cut-off frequency ω_{C1} of the HPF is a frequency before the cut-off frequency is changed through S11. The control signal CS for S5 is output from the controller 8a to the LPF-VGA 9.

As above, when the predetermined period (t1) elapses, the controller 8a returns the Q value of the LPF to the original Q value, which is the value before the Q value is lowered, during the predetermined period (t2) and changes the cut-off frequency ω_{C1} of the HPF into the frequency between the frequency before being raised and the raised frequency. When the predetermined period (t2) elapses, the controller 8a controls the two integrators so that the cut-off frequency ω_{C1} of the HPF returns to the original frequency acquired before being raised.

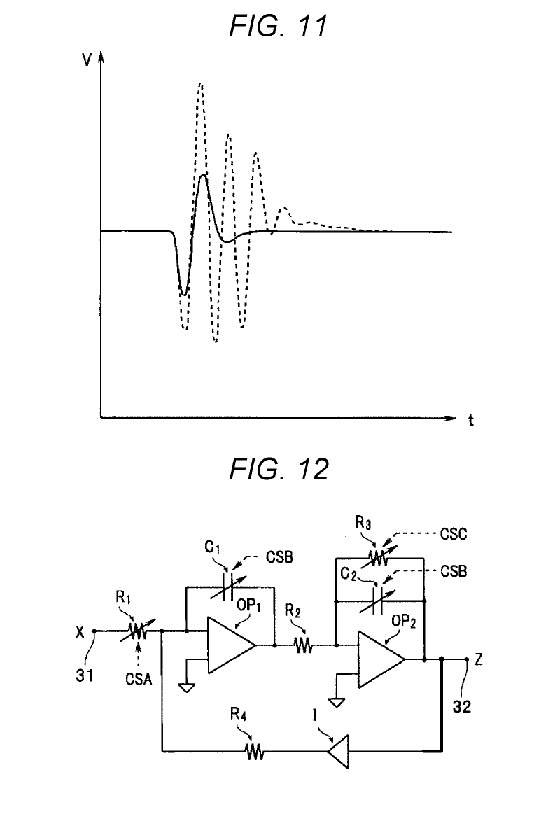

FIG. 11 is a graph illustrating the transient response characteristic of the DC offset when the process for the rapid convergence of the DC offset according to this embodiment is performed. The graph of FIG. 11 is acquired through simulation and shows qualitative characteristics. In FIG. 11, a horizontal axis indicates time t and a vertical axis indicates an offset voltage.

A solid line of FIG. 11 indicates the transient response characteristic in the DC offset output (voltage) when the process for the rapid convergence of the DC offset is performed according to this embodiment, and a dotted line indicates the transient response characteristic in the DC offset output (voltage) when the process for the rapid convergence of the DC offset is not performed according to this embodiment. The graph of FIG. 11 is acquired through simulation and shows qualitative characteristics.

As can be seen from FIG. 11, when the process for the rapid convergence of the DC offset is performed according to this embodiment, the offset output (voltage) of the biquad filter 11 rapidly converges as compared to the related art.

Therefore, in the case of the dotted line in FIG. 11, when the convergence time of the offset output of the VGA 15 is long and exceeds the time which is predetermined based on the communication standards, there is a concern that it is difficult to receive desired data. However, according to this embodiment, the offset output of the VGA 15 converges within the time which is predetermined based on the communication standards as depicted by the solid line, and thus it is possible to receive the desired data.

Therefore, according to this embodiment, it is possible to provide a filter that can change a gain and that can cause a transient response signal of DC offset, which is generated when the gain is changed, to rapidly converge in a wireless communication apparatus.

### Third Embodiment

In the first embodiment, when the gain is changed, the cut-off frequency ω_{C} of the LPF of the LPF-VGA 9 and the cut-off frequency ω_{C1} of the HPF are raised only during the predetermined period, thereby accomplishing the rapid convergence of the DC offset. In the second embodiment, when the gain is changed, the Q value of the LPF of the LPF-VGA 9 and the cut-off frequency ω_{C1} of the HPF are raised only during the predetermined period, thereby accomplishing the rapid convergence of the DC offset. On the other hand, in this embodiment, when the gain is changed, the cut-off frequency ω_{C} of the LPF of the LPF-VGA 9 and the cut-off frequency ω_{C1} of the HPF are raised and the Q value of the LPF of the LPF-VGA 9 is lowered only during the predetermined period, thereby accomplishing the further rapid convergence of the DC offset.

In this embodiment, the same reference numeral is attached to the same component as in the first and second embodiments and description thereof is not repeated.

The wireless receiver of this embodiment has the same configuration as in FIG. 1. The basic configuration of the LPF-VGA 9 of the wireless receiver has the same configuration as in FIG. 2.

FIG. 12 is a circuit diagram including the biquad filter 11 and the DC offset removal circuit 13 according to this embodiment. The biquad filter 12 and the DC offset removal circuit 14 have the same configuration as in FIG. 12 if the VGA 15 is removed. That is, in FIG. 2, the configuration of the circuit module 22 which includes the biquad filter 12 and the DC offset removal circuit 14 depicted by the two-short dashed line is the same as in FIG. 12.

The circuit illustrated in FIG. 12 has the three functions of low pass filter, variable gain amplifier and the DC offset removal, and has the approximately same configuration as in FIG. 3. However, the circuit illustrated in FIG. 12 is different from the circuit of FIG. 3 in that the resistor R₃ is a variable resistor.

The integrator I has the same configuration as in FIG. 4.

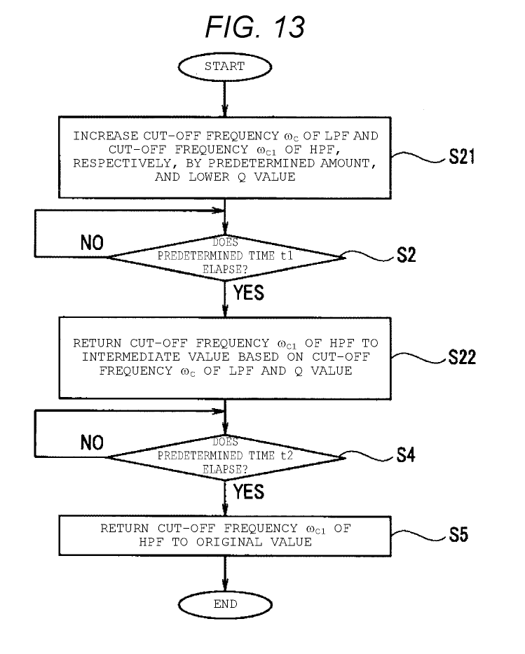

When a gain A is changed, the controller 8a performs the process for the rapid convergence of the DC offset. FIG. 13 is a flowchart illustrating an example of the flow of the process for the rapid convergence of the DC offset. Meanwhile, in FIG. 13, the same step number is attached to a process which is the same as in FIG. 5, and description thereof is not repeated.

The process in FIG. 13 is simultaneously performed with the operation to change the gain A when the gain A is changed. The process in FIG. 13 is performed by the hardware circuit in the controller 8a. When the gain A is changed, the controller 8a outputs the control signal CS to the biquad filters 11 and 12, the DC offset removal circuits 13 and 14, and the VGA 15 in the LPF-VGA 9.

The process in FIG. 13 is performed by combining the processes in FIGS. 5 and 10.

That is, when it is determined that the gain A is changed, the controller 8a increases the cut-off frequency ω_{C} of the LPF and the cut-off frequency ω_{C1} of the HPF of the circuit modules 21 and 22, respectively, and lowers the Q value by predetermined amount (S21).

After the process in S21 is performed, when a predetermined time t1 elapses in S2 (S2: YES), the cut-off frequency ω_{C} of the LPF and the Q value are returned to the original cut-off frequency and the original Q value and the cut-off frequency ω_{C1} of the HPF is returned to the intermediate value (S22).

The processes in S4 and S5 are the same as in FIG. 5.

That is, the controller 8a controls three integrators for the predetermined period (t1) according to a timing at which the gain is changed so that both of the cut-off frequency ω_{C} of the LPF and the cut-off frequency ω_{C1} of the HPF are raised and the Q value of LPF is lowered. Particularly, the controller 8a changes the Q value of the LPF by changing the resistance of the resistor R₃.

Therefore, in S21, the control signal CSB to change the cut-off frequency ω_{C} of the LPF and the cut-off frequency ω_{C1} of the HPF and the control signal CSC to lower the Q value are output from the controller 8a to the LPF-VGA 9.

Further, in S22, the control signal CSB to return the cut-off frequency ω_{C} of the LPF to an original cut-off frequency and to return the cut-off frequency ω_{C1} of the HPF to an intermediate value, and the control signal CSC to return the Q value to an original value are output from the controller 8a to the LPF-VGA 9.

That is, when the predetermined period (t1) elapses, the controller 8a returns the cut-off frequency ω_{C} of the LPF to the original frequency before being raised, returns the Q value of the LPF to the original Q value before being lowered, and changes the cut-off frequency ω_{C1} of the HPF to a frequency between the frequency before being raised and the raised frequency during the predetermined period (t2). When the predetermined period (t2) elapses, the controller 8a controls the three integrators so that the cut-off frequency ω_{C1} of the HPF is returned to the original frequency before being raised.

The other processes are the same as in FIG. 5.

In this embodiment, since both of the first and the second embodiments are implemented, the offset output of the LPF-VGA 9 converges within time which is predetermined based on communication standards, and thus it is possible to receive desired data.

Therefore, according to each of the above-described embodiments, it is possible to provide a filter that can change the gain and that can cause the transient response signal of the DC offset which is generated when the gain is changed to rapidly converge, and a wireless communication apparatus.

In addition, description has been given of the examples that the band-pass filter in each of the above-described embodiments is used in the wireless receiver. However, it is possible to use the band-pass filter in a wireless transmitter.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A band-pass filter circuit, comprising:
a low-pass filter;
a high-pass filter including an integrator; and
a controller configured to increase a cut-off frequency of the low-pass filter and a cut-off frequency of the high-pass filter for a predetermined period of time, when changing a gain of the low-pass filter.

2. The band-pass filter circuit according to claim 1, wherein
the controller is further configured to decrease the cut-off frequency of the low-pass filter to an original level after the predetermined period of time has passed.

3. The band-pass filter circuit according to claim 1, wherein
the controller is further configured to decrease the cut-off frequency of the high-pass filter to a level that is higher than an original level for a second predetermined period of time, after the predetermined period of time has passed, and then further decrease the cut-off frequency of the high-pass filter to the original level, after the second predetermined period of time has passed.

4. The band-pass filter circuit according to claim 1, wherein
the second predetermined time is longer than the predetermined time.

5. The band-pass filter circuit according to claim 1, wherein
the integrator includes at least one of a resistor and a capacitor, and
the controller increases the cut-off frequency of the high-pass filter by changing at least a resistance of the resistor or a capacitance of the capacitor.

6. The band-pass filter circuit according to claim 1, wherein
the low-pass filter includes a complete integrator including a resistor and a capacitor and an incomplete integrator including a resistor and a capacitor, and
the controller increases the cut-off frequency of the low-pass filter by changing at least one of the capacitors and the resistors of the complete and incomplete integrators.

7. The band-pass filter circuit according to claim 6, wherein
the integrator of the high-pass filter is provided in a feedback path between an output of the incomplete integrator and an input of the complete integrator.

8. The band-pass filter circuit according to claim 1, wherein
the controller is configured to decrease a Q value of the low-pass filter for the predetermined period of time, when changing the gain of the low-pass filter.

9. The band-pass filter circuit according to claim 8, wherein
the controller is configured to decrease the cut-off frequency and the Q value of the low-pass filter to original levels after the predetermined period of time has passed.

10. The band-pass filter circuit according to claim 9, wherein
the controller is further configured to decrease the cut-off frequency of the high-pass filter to a level that is higher than an original level for a second predetermined period of time, after the predetermined period of time has passed, and then further decrease the cut-off frequency of the high-pass filter to the original level, after the second predetermined period of time has passed.

11. A band-pass filter circuit, comprising:
a low-pass filter;
a high-pass filter including an integrator; and
a controller configured to decrease a Q value of the low-pass filter and increase a cut-off frequency of the high-pass filter for a predetermined period of time, when changing a gain of the low-pass filter.

12. The band-pass filter circuit according to claim 11, wherein
the controller is further configured to increase the Q value of the low-pass filter to an original level after the predetermined period of time has passed.

13. The band-pass filter circuit according to claim 11, wherein
the controller is further configured to decrease the cut-off frequency of the high-pass filter to a level that is higher than an original level for a second predetermined period of time, after the predetermined period of time has passed, and then further decrease the cut-off frequency of the high-pass filter to the original level, after the second predetermined period of time has passed.

14. The band-pass filter circuit according to claim 11, wherein
the integrator includes at least one of a resistor and a capacitor, and
the controller increases the cut-off frequency of the high-pass filter by changing at least a resistance of the resistor or a capacitance of the capacitor.

15. The band-pass filter circuit according to claim 11, wherein
the low-pass filter includes a complete integrator including a resistor and a capacitor and an incomplete integrator including a resistor and a capacitor, and
the controller decreases the Q value of the low-pass filter by changing at least one of the capacitors and the resistors of the complete and incomplete integrators.

16. The band-pass filter circuit according to claim 15, wherein
the integrator of the high-pass filter is provided in a feedback path between an output of the incomplete integrator and an input of the complete integrator.

17. A wireless communication module, comprising:
an antenna, a low noise amplifier, a mixer, a band-pass filter, an analog-to-digital converter, and a digital demodulator connected in series in this order, wherein
the band-pass filter includes a low-pass filter and a high-pass filter, and
a controller in the digital demodulator is configured to
change a gain of the low-pass filter based on an input therein, and
when changing the gain of the low-pass filter, perform at least one of increase of a cut-off frequency of the low-pass filter and decrease of a Q value of the low-pass filter for a predetermined period of time, and increase a cut-off frequency of the high-pass filter for the predetermined period of time.

18. The wireless communication module according to claim 17, wherein
when the controller increases the cut-off frequency of the low-pass filter, the controller decreases the cut-off frequency of the low-pass filter to an original level after the predetermined period of time has passed.

19. The wireless communication module according to claim 17, wherein
when the controller decreases the Q value of the low-pass filter, the controller increases the Q value to an original level after the predetermined period of time has passed.

20. The wireless communication module according to claim 17, wherein
the controller is further configured to decrease the cut-off frequency of the high-pass filter to a level that is higher than an original level for a second predetermined period of time, after the predetermined period of time has passed, and then further decrease the cut-off frequency of the high-pass filter to the original level, after the second predetermined period of time has passed.
